(19) United States
(12) Patent Application Publication
(10) Pub. No.: US 2026/0025606 A1
(43) Pub. Date: Jan. 22, 2026

(54) SPEAKER COVER ASSEMBLY AND METHOD OF ASSEMBLING SAME

(71) Applicant: Paul Howey, Monroe, MI (US)

(72) Inventor: Paul Howey, Monroe, MI (US)

(21) Appl. No.: 19/270,877

(22) Filed: Jul. 16, 2025

Related U.S. Application Data
(60) Provisional application No. 63/671,973, filed on Jul. 16, 2024.

(51) Int. Cl. H04R 1/02; H05K 5/03

(52) U.S. Cl. CPC H04R 1/023; H04R 1/025; H05K 5/03; H04R 2201/029

(57) ABSTRACT

A speaker cover assembly includes a body having a front portion defining a front surface. The speaker cover assembly also includes a sidewall having a generally tubular shape that extends axially from the front portion to a rim. The rim is configured to engage and seal against at least one of a speaker box or an audio actuator. The speaker cover assembly also includes at least one connection feature for connecting the speaker cover assembly to the speaker box. The speaker cover assembly is formed of silicone material and suctions to a provided speaker box.

### CROSS REFERENCE TO RELATED APPLICATIONS

This U.S. utility patent application claims the benefit of U.S. Provisional Patent Application No. 63/671,973, filed Jul. 16, 2024, the contents of which is incorporated herein by reference in its entirety.

### TECHNICAL FIELD

This disclosure relates to a speaker cover assembly and a method of assembling same and in particular to a speaker cover for waterproofing conventional audio speakers.

### BACKGROUND

This section provides background information related to the present disclosure which is not necessarily prior art.

The invention of audio speakers has resulted in the widespread availability of music and dissemination of other audio-based information to the general public. For personal use, families and friends gather together to listen to music, podcasts, etc. For professional use, speakers have been adopted as a popular tool for dissemination of audio instructions and communications.

Traditional speakers can be found virtually everywhere, and are oftentimes a central component to everyday life. Over the years, improvements in speaker technology have been a result of necessities in audio quality and the widespread adoption of various electronics. These improvements have led to an improvement in audio quality, a wider range of volume options, and a significantly reduced packaging. While these improvements have provided widespread availability and portability to the masses, there are still persistent shortcomings. For example, many of these improvements have resulted in increased costs and have overlooked certain protective measures instead focusing on convenience to an end-user. For example, a vast majority of speakers are not waterproof or even water resistant and thus can be negatively impacted by exposure to the elements including water, dust, and debris. Because speakers are more portable now than ever, speakers are now oftentimes brought outside for events like camping, grilling, tailgating, and boating. As such, these speakers can become damaged in the event of rain, wind, and other environmental conditions.

Accordingly, there is a continued interest in providing adaptability to speakers for various environmental conditions.

### SUMMARY

The present disclosure provides a speaker cover assembly. The speaker cover assembly includes a body having a front portion defining a front surface. The speaker cover assembly also includes a sidewall having a generally tubular shape that extends axially from the front portion to a rim, wherein the rim is configured to engage and seal against at least one of a speaker box or an audio actuator. The speaker cover assembly also includes at least one connection feature for connecting the speaker cover assembly to the speaker box.

The present disclosure also provides a method of forming a speaker box assembly. The method includes: measuring an opening in a speaker box; forming a speaker cover assembly to fit over the opening; forming at least one connection feature in the speaker cover assembly; and attaching the speaker cover assembly over the opening.

These and other aspects of the present disclosure are disclosed in the following detailed description of the embodiments, the appended claims, and the accompanying figures.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 generally illustrates a speaker box and a speaker cover assembly according to the principles of the present disclosure.

FIG. 2 generally illustrates a front the speaker cover assembly according to the principles of the present disclosure.

FIG. 3 generally illustrates a front of the speaker cover assembly according to the principles of the present disclosure.

FIG. 4 generally illustrates a side of the speaker cover assembly according to the principles of the present disclosure.

FIGS. 5A-5B generally illustrates the speaker cover assembly according to the principles of the present disclosure.

FIG. 6 generally illustrates a front of the speaker cover assembly being attached to a speaker grill cover according to the principles of the present disclosure.

FIG. 7 generally illustrates a cross-section of a speaker cover assembly according to the principles of the present disclosure.

FIG. 8 generally illustrates a cross-section of a speaker cover assembly according to the principles of the present disclosure.

FIG. 9 generally illustrates a cross-section of a speaker cover assembly according to the principles of the present disclosure.

FIG. 10 generally illustrates a front of a speaker cover assembly with a protruding tab, according to an aspect of the present disclosure.

FIG. 11 shows a cross-section of the speaker cover assembly according to the principles of the present disclosure.

FIG. 12 generally illustrates a method of assembling the speaker cover assembly.

### DETAILED DESCRIPTION

The following discussion is directed to various embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

As described, the invention of audio speakers have resulted in the widespread availability of music and dissemination of other audio-based information to the general public. For personal use, families and friends gather together to listen to music, podcasts, etc. For professional use, speakers have been adopted as a popular tool for dissemination of audio instructions and communications.

Traditional speakers can be found virtually everywhere, and are oftentimes a central component to everyday life. Over the years, improvements in speaker technology have been a result of necessities in audio quality and the widespread adoption of various electronics. These improvements have led to an improvement in audio quality, a wider range of volume options, and a significantly reduced packaging. While these improvements have provided widespread availability and portability to the masses, there are still persistent shortcomings. For example, many of these improvements have resulted in increased costs and have overlooked certain protective measures instead focusing on convenience to an end-user. For example, a vast majority of speakers are not waterproof or even water resistant and thus can be negatively impacted by exposure to the elements including water, dust, debris, and degradation due to exposure to sunlight. Because speakers are more portable now than ever, speakers are now oftentimes brought outside for events like camping, grilling, tailgating, and boating. As such, these speakers can become damaged in the event of rain, wind, and other environmental conditions.

Accordingly, a speaker cover assembly and method of assembling same, such as those described herein, configured to provide a adaptability to an audio speaker in various outdoor environments, may be desirable. In some embodiments, the speaker cover assembly and method of assembling same described herein may be configured provide a protective film over a provided speaker.

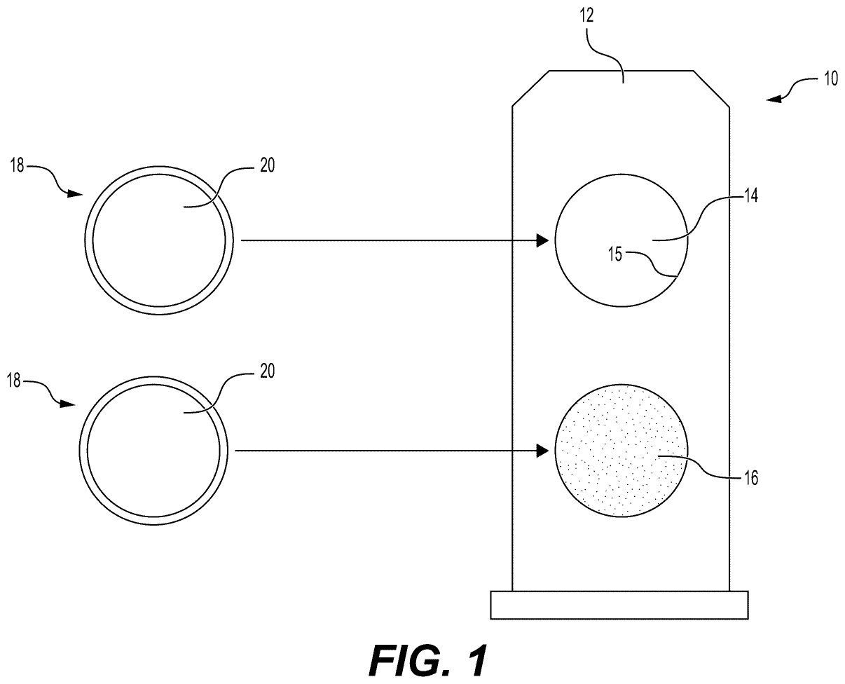

FIG. 1 generally illustrates a speaker box 10 according to the principles of the present disclosure. The speaker box 10 may include any suitable speaker box, such as those for recreational use and professional use, speaker boxes that are part of larger audio or audio visual assemblies, other speaker boxes, or combinations thereof. The speaker box 10 may be formed, at least partially, by a panel of a vehicle, such as a door panel of a car or truck or an interior panel of a boat. The speaker box 10 includes a housing 12 that holds electronic components that are susceptible to damage from environmental conditions. The speaker box 10 further includes one or more audio actuators 14 that receive audio signals from the electronic components in the housing 12. The audio actuators 14 may be visible in one or more openings 15 defined by the housing 12. The audio actuators 14 may include speakers, subwoofers, interior baskets, other conventional components, and combinations thereof. At least one of the audio actuators 14 may include a speaker grill cover 16.

With continued reference to FIG. 1, a first speaker cover assembly 18 is generally indicated. The first speaker cover assembly 18 includes a body 20 that may be generally integral and be formed of a plastic, a soft rubber such as silicone, and/or one or more other materials that are generally waterproof or water resistant, or combinations thereof. Additionally, the first speaker cover assembly 18 of the present disclosure may protect a speaker from being damaged due to ultraviolet light, such as from exposure to sunlight. The body 20 may be circular-shaped and define an outer circumference 22 for sealing against or otherwise operatively connecting to the speaker box 10. In operation, the first speaker cover assembly 18 may be located over the audio actuator 14 on an inside or an outside of the speaker grill cover 16 and provide water and weather proofing to an otherwise conventional speaker box 10.

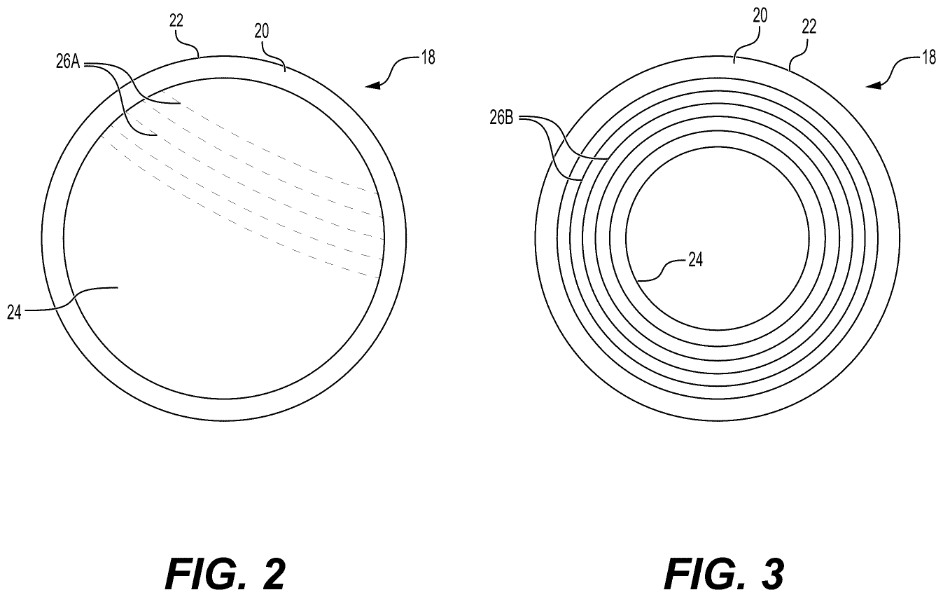

As best illustrated in FIGS. 2 and 3, the body 20 includes a front surface 24 that may define topographical features, e.g., indentations, ribs, or combinations thereof. The topographical features may be aesthetic or performance based. For example, first topographical features 26A presented in FIG. 2 provide a series of wave-like indentations for providing a certain amount of flexibility of the body 20 to accurately disseminate sound therethrough. The wave-like indentations include parallel and curved rib-shaped indentations within the front surface 24. The wave-like indentations may be eccentric with the circular shape of the body 20, with curves of the wave-like indentations intersecting a peripheral edge of the front surface 24 at two points. In some embodiments, the wave-like indentations may define steps or ramps. The first topographical features 26A may have a step-shaped, triangular wave, or sawtooth shaped cross-section. In some embodiments, and as shown in FIG. 2 the wave-like indentations may have irregular spacing. Alternatively, the wave-like indentations may be spaced apart at regular intervals or at progressively increasing intervals. Similarly, second topographical features 26B shown in FIG. 3 include a series of circumferential steps in the front surface 24 for providing a certain amount of flexibility of the body 20 to accurately disseminate sound therethrough.

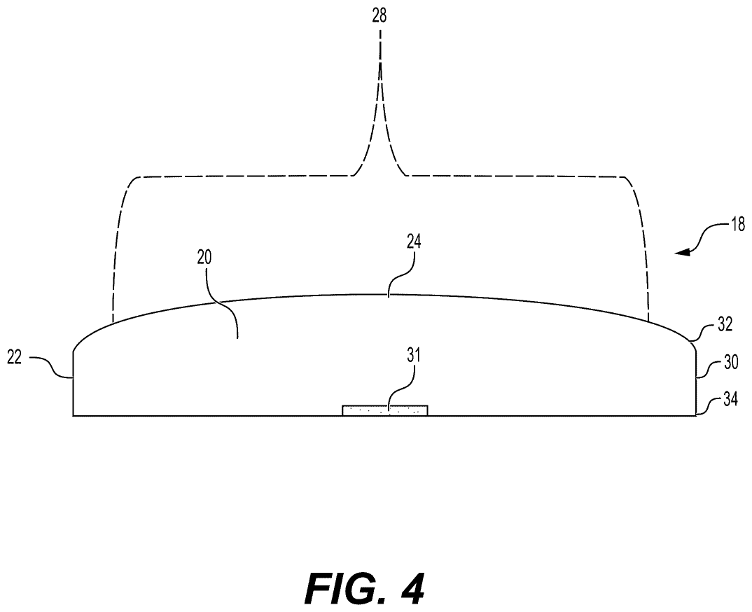

With reference now to FIG. 4, first speaker cover assembly 18 is illustrated from a side orientation. The body 20 is shown to include a front portion 28, associated with the front surface 24 and a sidewall 30 for spacing the front portion 28 from the audio actuator 14 for preventing muffling of an audio output. In some embodiments, the front portion 28 merges into the sidewall 30 at a rounded portion 32. In some embodiments, the front portion 28 may include a rounded profile from the sidewall 30. The rounded profile may be circular, elliptical, or some other shape. The sidewall 30 has a generally tubular shape that extends axially from the front portion 28 to a rim 34. The rim 34 may be configured to engage and seal against the speaker box and/or the audio actuator 14. The rim 34 may extend on a single plane or be shaped to conform with a non-flat speaker box 10. In some embodiments, and as shown on FIG. 4, the rim 34 of the sidewall 30 may define a recess 31, which may have a rectangular shape, to conform to a structure on the speaker box 10, such as a retainer tab for holding a speaker or a grille cover. However, the recess 31 may have another shape, which may depend on design details of the speaker box 10 or other associated hardware.

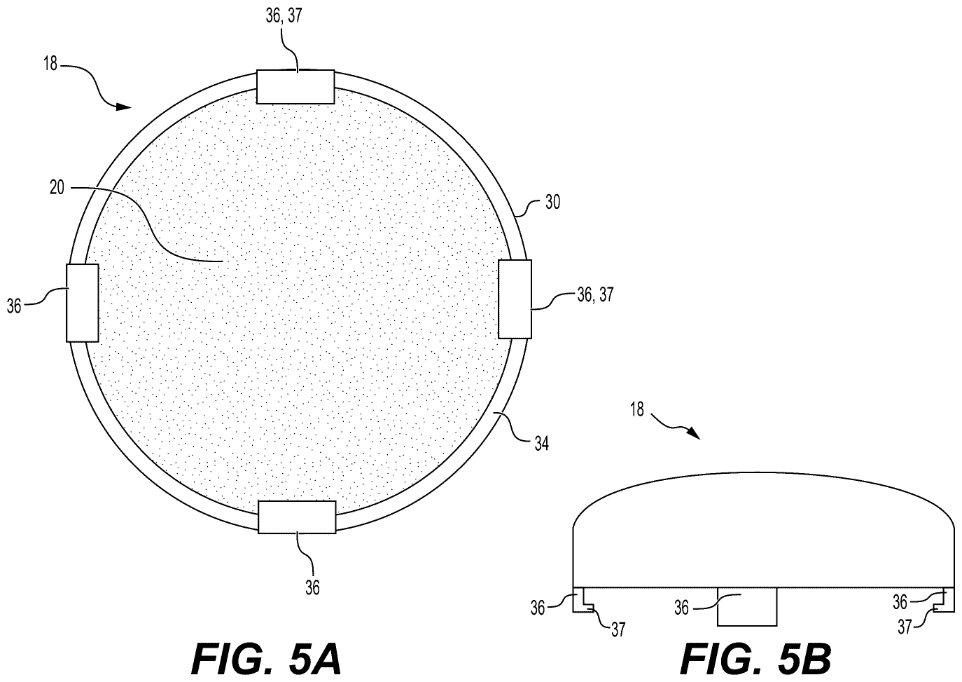

FIG. 5A shows a back view of the first speaker cover assembly 18, opposite of a front view that an observer would see when the first speaker cover assembly 18 is installed on the speaker box 10. FIG. 5B shows a side view of the first speaker cover assembly 18. As best illustrated in FIGS. 5A-5B, a plurality of connection features 36 may be located on the rim 34. The connection features 36 are disposed at regular angular intervals around the sidewall 30. The first speaker cover assembly 18 may include four of the connection features 36 spaced apart at 90-degree intervals. However, there may be a different number and/or a different arrangement of the connection features 36. The connection features 36 extend from the rim 34, away from the front portion 28. Each of the connection features 36 also includes a protrusion 37 that extends radially inward and which is spaced apart from the rim 34. The protrusion 37 may engage a corresponding recess on the speaker box 10 and/or on the audio actuators 14. Additionally or alternatively, the connection features 36 may include snap on clips, indent clips, an adhesive, a fastener, a flexible lip that allows it to suction onto or otherwise friction fit on the speaker box 10 with a tight tolerance, or a combination thereof. In some embodiments, indent clips and a flexible lip are provided. In some embodiments, the connection feature 36 may be integrally formed with the body 20 of the first speaker cover assembly 18.

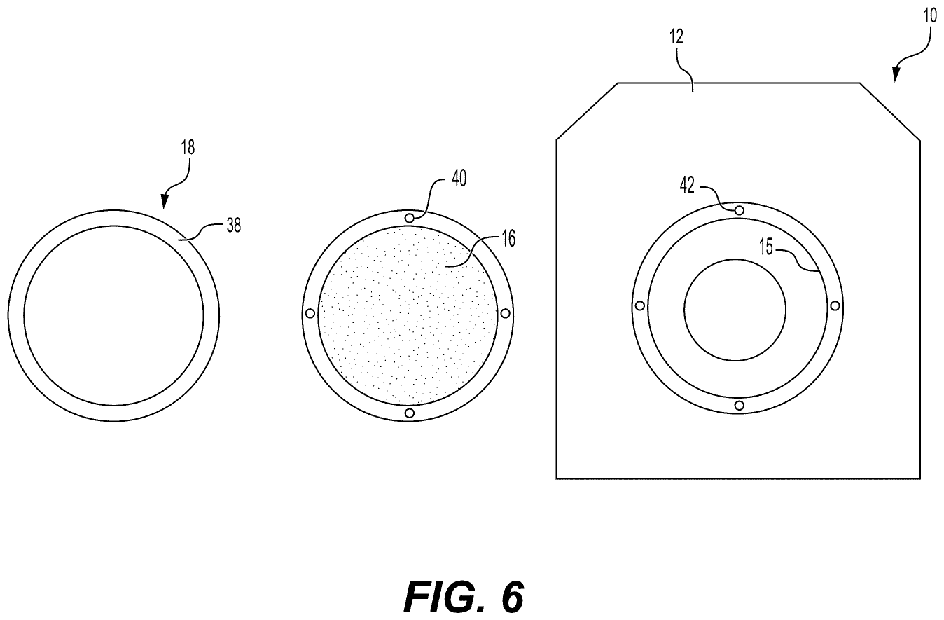

With reference now to FIG. 6A, the connection feature 36 may further include a flange 38 that has a similar profile to the speaker grill cover 16. Thus, fasteners, such as screws (not shown) can be driven through the flange 38 and first holes 40 in the speaker grill cover 16 and into second holes 42 on the speaker box 10. In some embodiments, the flange 38 may include pilot apertures (not shown), which may be smaller than the corresponding holes 40, 42. The flange 38 may be stretched or deformed at the pilot apertures to seal against a fastener that is inserted therein. The first speaker cover assembly 18 may be placed on the outside of the speaker grill cover 16. Alternatively, the flange 38 may be located inside of the speaker grill cover 16, between the speaker grill cover 16 and the speaker box 10.

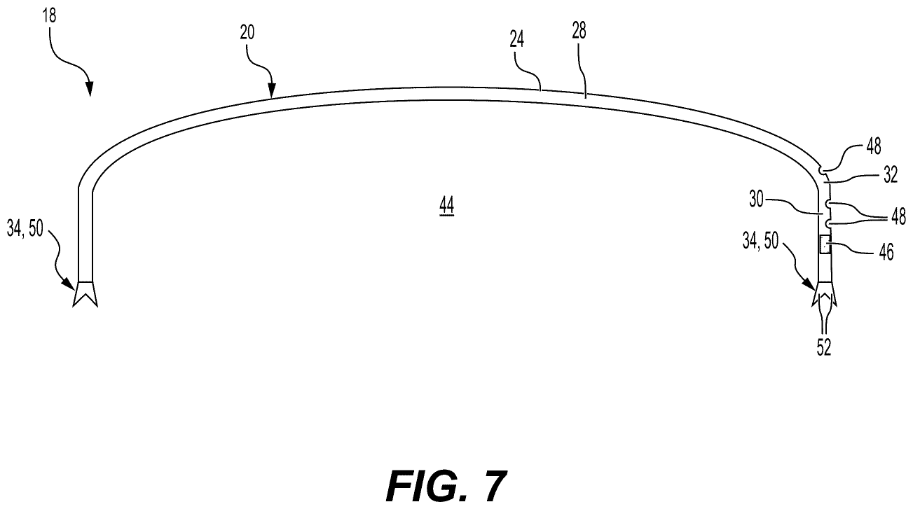

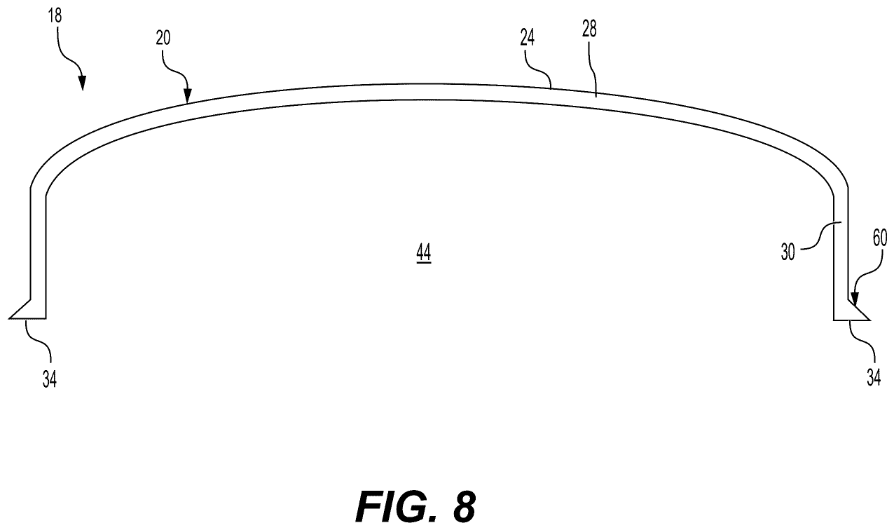

FIG. 7 illustrates a cross-section of the first speaker cover assembly 18 in accordance with an embodiment of the disclosure. The rim 34 includes a forked structure 50 having at least two annular projections 52 that each extend away from one another and to a peak, opposite from the front portion 28. During connection, a suction vacuum may be formed between the annular projections of the forked surface 35 and within a cavity 44 defined by the sidewalls 30. A support ring 46 is disposed inside of the sidewall 30 of the body 20 and is spaced from the rim 34 to provide support to the first speaker cover assembly 18 in a circumferential direction while also allowing circumferential flexing and suction functionality of the sidewall 30 near the rim 34. The support ring 46 may be made of a material that is different from the body 20. The support ring 46 may be made of a material that is more rigid and/or less elastic than a material of the body 20. The support ring 46 may be made of metal, such as steel or aluminum. Alternatively, the support ring 46 may be made of a polymer, such as nylon, high-density polyethylene (HDPE), polyethylene terephthalate (PET), polypropene (PP), or acrylonitrile butadiene styrene (ABS). In some embodiments, the first speaker cover assembly 18 may include two or more support rings 46.

In some embodiments, and as also shown in FIG. 7, the body 20 may define one or more relief grooves 48 for allowing the body 20 to flex during audio output. The relief grooves 48 may extend into an outer surface of the sidewall 30 and/or the rounded portion 32 of the body 20. In other words, and as shown on FIG. 7, the front portion 28 may define at least one of the relief grooves 48, which may be spaced apart from the sidewall 30. The relief grooves 48 may extend circumferentially entirely around the body 20. Alternatively, relief grooves 48 may extend only part-way circumferentially around the body 20. In some embodiments (not shown on the FIGs.), the relief grooves 48 may include a plurality of arcuate grooves at regular angular intervals to define interrupted arrangement extending circumferentially around the body 20. In some embodiments, and as shown in FIG. 7, the sidewall 30 may define two or more of the relief grooves 48, and the rounded portion 32 may define one or more of the relief grooves 48. In some embodiments, the support ring 46 may be located between the rim 34 and at least one of the relief grooves 48. In some embodiments, at least one of the support rings 46 may be located between two of the relief grooves 48.

FIG. 8 illustrates a cross-section of the first speaker cover assembly 18 in accordance with an embodiment of the disclosure. The rim 34 defines a first flared base 60 with a generally trapezoidal cross-section, but otherwise presents a substantially flat suctioning surface. As shown, the first flared base 60 tapers to a point along a path extending radially outwardly. However, the first flared base 60 may have another shape, such as a rounded or squared-off tip at its radially-outermost edge. Additionally or alternatively, the first flared base 60 may also include another portion (not shown on FIG. 8) that tapers to a point along a path extending radially inwardly.

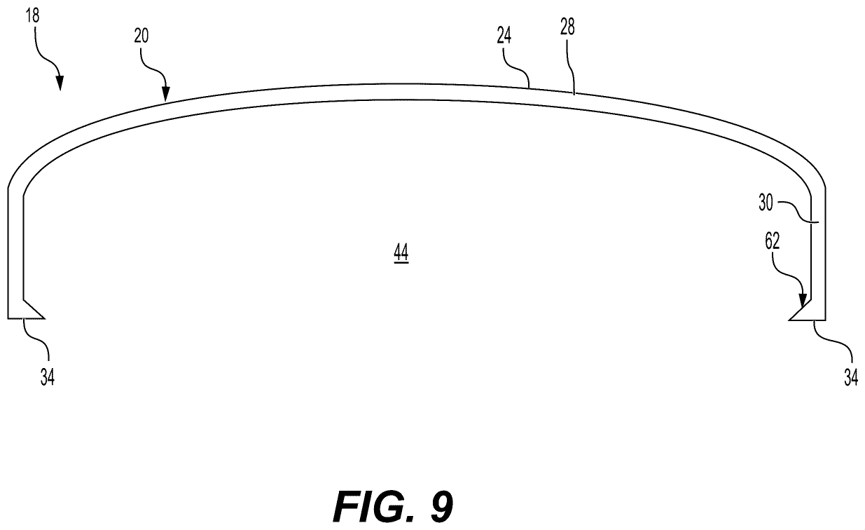

FIG. 9 illustrates a cross-section of the first speaker cover assembly 18 in accordance with another embodiment of the disclosure. The rim 34 defines a second flared base 62 with a generally trapezoidal cross-section, but otherwise presents a substantially flat suctioning surface. As shown, the second flared base 62 tapers to a point along a path extending radially inwardly. However, the second flared base 62 may have another shape, such as a rounded or squared-off tip at its radially-innermost edge. Additionally or alternatively, the second flared base 62 may also include another portion (not shown on FIG. 9) that tapers to a point along a path extending radially outwardly, and which may be similar or identical to the first flared base 60.

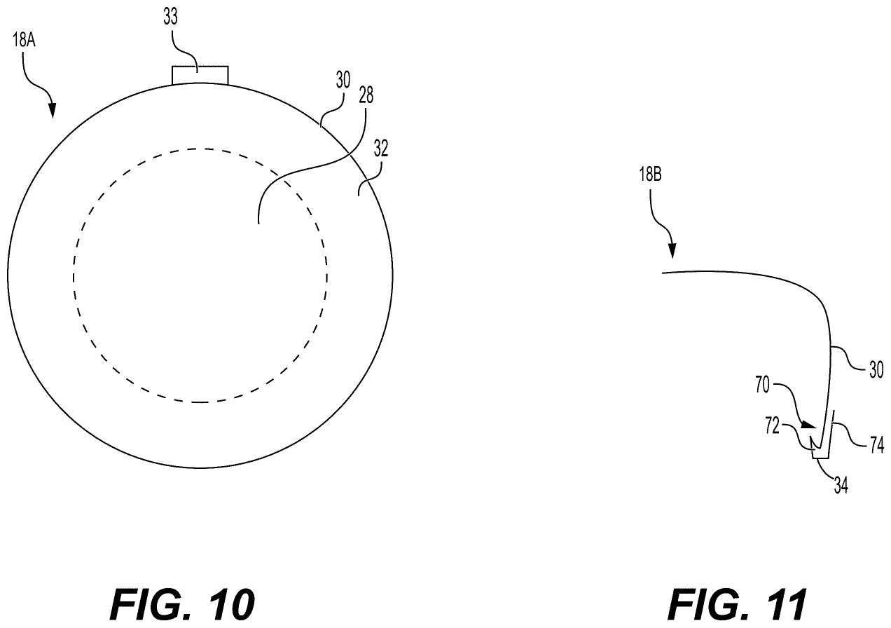

FIG. 10 shows an embodiment of a second speaker cover assembly 18a with the protruding tab 33, which extends radially outwardly from the sidewall 30, and which may facilitate removing the second speaker cover assembly 18a from an installed configuration. The second speaker cover assembly 18a may be a variation of the first speaker cover assembly 18, and may be identical to the first speaker cover assembly 18, except for differences shown and/or described in the present disclosure.

FIG. 11 shows an embodiment of a third speaker cover assembly 18b with a clip 70 for securing the third speaker cover assembly 18b to a speaker or other structure. The third speaker cover assembly 18b may be a variation of the first speaker cover assembly 18, and may be identical to the first speaker cover assembly 18 and/or the second speaker cover assembly 18a, except for differences shown and/or described in the present disclosure. The clip 70 may have a structure that is similar to the forked structure 50 of shown in FIG. 7, the first flared base 60 of FIG. 8, and/or the second flared base 62 of FIG. 9. The clip 70 includes a hooked portion 72 that extends away from the rim 34 and radially inward from the sidewall 30. The hooked portion 72 may engage a corresponding recess on the speaker box 10 and/or on the audio actuators 14 for attaching the third speaker cover assembly 18b thereto. The clip 70 also includes a tab portion 74 that is located outside of the sidewall 30 and which extends upwardly, away from the rim 34 and parallel to the sidewall 30 to facilitate removing the third speaker cover assembly 18b from a speaker box 10.

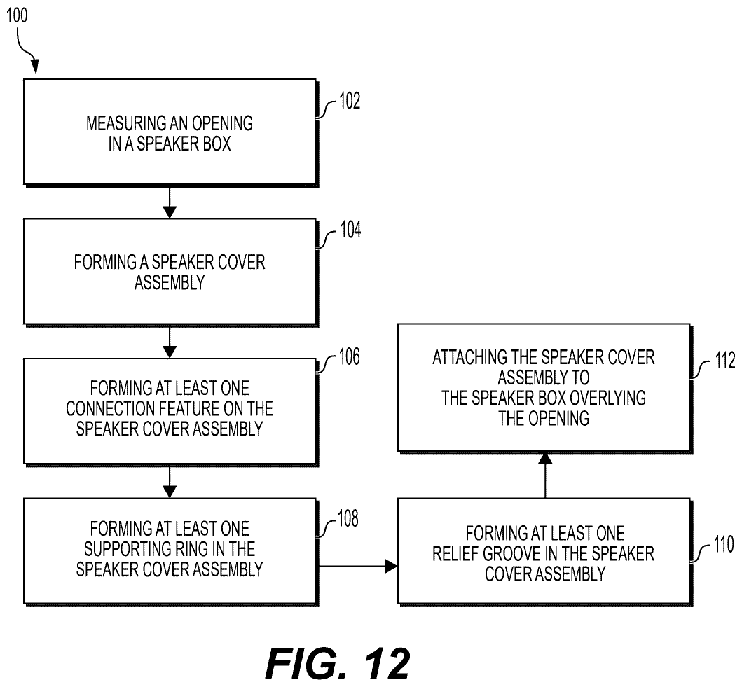

FIG. 12 is a flow diagram generally illustrating a method 100 of forming the first speaker cover assembly 18 according to the principles of the present disclosure. At 102, the method 100 includes measuring an opening for a speaker box that houses an audio actuator. At 104, the method 100 includes forming a speaker cover assembly that has a circumference large enough to cover the opening. Step 104 may include molding or otherwise forming the speaker cover assembly of a resilient material, such as soft rubber or silicone. At 106, the method 100 includes forming at least one connection feature on the speaker cover assembly. At 108, the method 100 includes forming a support ring 46 in the speaker cover assembly. At 110, the method 100 includes forming at least one relief groove. At 112, the method 100 includes attaching the speaker cover assembly to the speaker box overlying the opening. Attaching the speaker cover assembly at step 112 may include sealing or otherwise connecting attaching the speaker cover assembly to the speaker box. Attaching the speaker cover assembly at step 112 may include installing the speaker cover assembly to extend annularly around the opening in the speaker box.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

The word “example” is used herein to mean serving as an example, instance, or illustration. Any aspect or design described herein as “example” is not necessarily to be construed as preferred or advantageous over other aspects or designs. Rather, use of the word “example” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an implementation” or “one implementation” throughout is not intended to mean the same embodiment or implementation unless described as such.

The above-described embodiments, implementations, and aspects have been described in order to allow easy understanding of the present disclosure and do not limit the present disclosure. On the contrary, the disclosure is intended to cover various modifications and equivalent arrangements included within the scope of the appended claims, which scope is to be accorded the broadest interpretation to encompass all such modifications and equivalent structure as is permitted under the law.

What is claimed is:

1. A speaker cover assembly, comprising:
a body including a front portion defining a front surface, and sidewall having a generally tubular shape that extends axially from the front portion to a rim, wherein the rim is configured to engage and seal against at least one of a speaker box or an audio actuator; and
at least one connection feature for connecting the speaker cover assembly to the speaker box.

2. The speaker cover assembly of claim 1, wherein the body and the sidewall are formed of silicone.

3. The speaker cover assembly of claim 1, wherein the at least one connection feature includes a plurality of connection features disposed at regular angular intervals around the sidewall.

4. The speaker cover assembly of claim 3, wherein the plurality of connection features includes four of the connection features disposed at regular angular intervals of 90-degrees.

5. The speaker cover assembly of claim 1, wherein the at least one connection feature extends from the rim, away from the front portion, and wherein the at least one connection feature includes a protrusion that extends radially inward and which is spaced apart from the rim.

6. The speaker cover assembly of claim 1, wherein the rim includes a forked structure having at least two annular projections that each extend away from one another and to a peak, opposite from the front portion.

7. The speaker cover assembly of claim 1, wherein the rim includes a flared base with a generally trapezoidal cross-section.

8. The speaker cover assembly of claim 7, wherein the generally trapezoidal cross-section of the flared base tapers to a point along a path extending radially outwardly.

9. The speaker cover assembly of claim 7, wherein the generally trapezoidal cross-section of the flared base tapers to a point along a path extending radially inwardly.

10. The speaker cover assembly of claim 1, wherein the rim includes a clip for securing the speaker cover assembly to a speaker or other structure, and wherein the clip includes a hooked portion that extends away from the rim and radially inward from the sidewall.

11. The speaker cover assembly of claim 10, wherein the clip further includes a tab portion to facilitate removing the speaker cover assembly from a speaker box, wherein the tab portion is located outside of the sidewall and extends away from the rim.

12. The speaker cover assembly of claim 1, further comprising a support ring disposed inside of the sidewall and spaced from the rim to provide support in a circumferential direction.

13. The speaker cover assembly of claim 12, wherein the support ring is made of metal.

14. The speaker cover assembly of claim 12, wherein the support ring is made of a polymer material.

15. The speaker cover assembly of claim 1, wherein the body defines one or more relief grooves extending circumferentially for allowing the body to flex during audio output.

16. The speaker cover assembly of claim 15, wherein the one or more relief grooves includes two of the relief grooves in the sidewall.

17. The speaker cover assembly of claim 15, wherein the one or more relief grooves includes at least one relief groove in the front portion, spaced apart from the sidewall.

18. The speaker cover assembly of claim 1, wherein the body defines a circular shape, wherein the front surface of the front portion defines a plurality of wave-like indentations, and wherein each indentation of the plurality of wave-like indentations has a curve eccentric with the circular shape of the body and which intersects a peripheral edge of the front surface at two points.

19. A method of forming a speaker box assembly comprising:
measuring an opening in a speaker box;
forming a speaker cover assembly to fit over the opening;
forming at least one connection feature in the speaker cover assembly; and
attaching the speaker cover assembly over the opening.

20. The method of forming a speaker box assembly of claim 19, wherein forming the speaker cover assembly includes forming the speaker cover assembly of silicone.
